(19) United States
(12) Patent Application Publication
(10) Pub. No.: US 2024/0355647 A1
(43) Pub. Date: Oct. 24, 2024

(54) SUBSTRATE PROCESSING METHOD AND SUBSTRATE PROCESSING SYSTEM

(71) Applicant: Tokyo Electron Limited, Tokyo (JP)

(72) Inventors: Takashi UNO, Koshi City, Kumamoto (JP); Naoyuki OKAMURA, Koshi City, Kumamoto (JP); Katsufumi MATSUKI, Koshi City, Kumamoto (JP); Keisuke SAKAGUCHI, Koshi City, Kumamoto (JP)

(21) Appl. No.: 18/686,540

(22) PCT Filed: Aug. 5, 2022
(86) PCT No.: PCT/JP2022/030135

§ 371 Date: Feb. 26, 2024

(30) Foreign Application Priority Data
Aug. 27, 2021 (JP) 2021-138875

(51) Int. Cl. H01L 21/67; H01L 21/306; H01L 21/311; H01L 21/687

(52) U.S. Cl. CPC H01L 21/67063; H01L 21/30604; H01L 21/31111; H01L 21/68764

(57) ABSTRACT

A substrate processing method of processing a substrate includes etching a surface of the substrate by supplying an etching liquid containing hydrofluoric acid and phosphoric acid to the surface of the substrate; collecting the etching liquid after being used in the etching; measuring a thickness distribution of the substrate after being etched; and adjusting a composition ratio of the etching liquid by adding, based on the measured thickness distribution, at least hydrofluoric acid or phosphoric acid to the etching liquid collected after being used in the etching.

### TECHNICAL FIELD

The various aspects and embodiments described herein pertain generally to a substrate processing method and a substrate processing system.

### BACKGROUND

Patent Document 1 discloses a manufacturing method for a semiconductor wafer, including a process of flattening at least a surface of a wafer obtained by slicing a semiconductor ingot, and a process of etching the surface of the flattened wafer by spin etching.

### PRIOR ART DOCUMENT

Patent Document 1: Japanese Patent Laid-open Publication No. H11-135464

### DISCLOSURE OF THE INVENTION

### Problems to be Solved by the Invention

Exemplary embodiments provide a technique capable of appropriately controlling a surface shape of a substrate after being etched when etching a plurality of substrates while reusing an etching liquid.

### Means for Solving the Problems

In an exemplary embodiment, a substrate processing method of processing a substrate includes etching a surface of the substrate by supplying an etching liquid containing hydrofluoric acid and phosphoric acid to the surface of the substrate; collecting the etching liquid after being used in the etching; measuring a thickness distribution of the substrate after being etched; and adjusting a composition ratio of the etching liquid by adding, based on the measured thickness distribution, at least hydrofluoric acid or phosphoric acid to the etching liquid collected after being used in the etching.

### Effect of the Invention

According to the exemplary embodiment, it is possible to appropriately control the surface shape of the substrate after being etched when etching the plurality of substrates while reusing the etching liquid.

### BRIEF DESCRIPTION OF THE DRAWINGS

FIG. 1 is a plan view illustrating a schematic configuration of a wafer processing system according to an exemplary embodiment.

FIG. 2 is a side view illustrating a schematic configuration of an etching device.

FIG. 3 is a flowchart illustrating main processes of a wafer processing.

FIG. 4A to FIG. 4C are explanatory diagrams illustrating the main processes of the wafer processing.

FIG. 5 is a graph showing a variation in an etching amount when no component is added to an etching liquid to be reused.

FIG. 6 is a graph showing a variation in an etching amount when hydrofluoric acid is added to the etching liquid to be reused.

FIG. 7 is a graph showing a variation in an etching amount when hydrofluoric acid and nitric acid are added to the etching liquid to be reused.

FIG. 8 is a graph showing a variation in an etching amount when hydrofluoric acid, nitric acid and phosphoric acid are added to the etching liquid to be reused.

FIG. 9 is an explanatory diagram showing a relationship between the components added to the etching liquid and an etching amount average/an etching amount range.

### DETAILED DESCRIPTION

In a manufacturing process for a semiconductor device, a cut surface of a disk-shaped silicon wafer (hereinafter, simply referred to as “wafer”) cut from a single crystalline silicon ingot with a wire saw or the like is flattened and smoothed to uniformize the thickness of the wafer. The flattening of the cut surface is performed by, for example, surface grinding or lapping. The smoothing of the cut surface is performed by, for example, spin etching of supplying an etching liquid from above the cut surface of the wafer while rotating the wafer.

It is described in the aforementioned Patent Document 1 that at least a surface of a wafer obtained by slicing a semiconductor ingot is flattened by surface grinding or lapping and is then etched by spin etching. In the spin etching process described in Patent Document 1, a mixed acid is used as an etching liquid.

Here, from the viewpoint of reducing consumption of the etching liquid in the etching, it is desirable to collect the etching liquid used for one wafer and reuse it for other wafers. When the used etching liquid is collected and reused in this way, a composition ratio of the etching liquid is changed due to a reaction between the wafer (silicon) and the etching liquid (mixed acid). As a result, an etching amount and an etching profile are changed, which in turn results in unstable etching performance.

However, the etching method described in Patent Document 1, for example, does not mention anything about reusing the etching liquid in this way and anything about the aforementioned problem. In this regard, there is a room for improvement in the conventional etching processing.

The present disclosure provides a technique capable of appropriately controlling a surface shape of a substrate after being etched when etching a plurality of substrates while reusing an etching liquid. Hereinafter, a wafer processing system as a substrate processing system and a wafer processing method as a substrate processing method according to an exemplary embodiment will be described with reference to the accompanying drawings. In the present specification and the drawings, parts having substantially same functions and configurations will be assigned same reference numerals, and redundant description thereof will be omitted.

In a wafer processing system 1 according to the present exemplary embodiment, a wafer W as a substrate cut from an ingot is subjected to a processing of improving in-surface uniformity of the thickness thereof. Hereinafter, the cut surfaces of the wafer W will be respectively referred as a first surface Wa and a second surface Wb. The first surface Wa is a surface opposite to the second surface Wb. The first surface Wa and the second surface Wb may sometimes be collectively referred to as a surface of the wafer W.

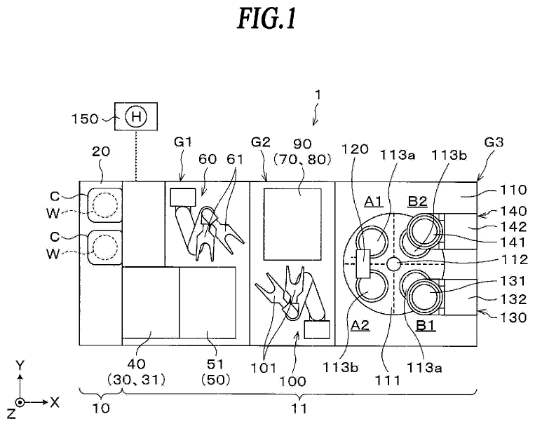

As depicted in FIG. 1, the wafer processing system 1 has a configuration in which a carry-in/out station 10 and a processing station 11 are connected as one body. In the carry-in/out station 10, a cassette C capable of accommodating therein a plurality of wafers W, for example, is carried to and from the outside. The processing station 11 is equipped with various types of processing apparatuses configured to perform required processings on the wafer W.

The carry-in/out station 10 is provided with a cassette placing table 20. In the shown example, the cassette placing table 20 is configured to place thereon a plurality of, for example, two cassettes C in a row in the Y-axis direction.

The processing station 11 is equipped with, for example, three processing blocks G1 to G3. The first processing block G1, the second processing block G2, and the third processing block G3 are arranged in this order from the negative X-axis side (carry-in/out station 10 side) to the positive X-axis side.

The first processing block G1 is equipped with inverting devices 30 and 31, a thickness measuring device 40, etching devices 50 and 51 as liquid processing apparatuses, and a wafer transfer device 60. The inverting device 30 and the etching device 50 are arranged in this order from the negative X-axis side to the positive X-axis side. The inverting devices 30 and 31 and the thickness measuring device 40 are stacked in this order from the bottom in a vertical direction, for example. The etching devices 50 and 51 are stacked in this order from the bottom in the vertical direction, for example. The wafer transfer device 60 is disposed on the positive Y-axis side of the etching devices 50 and 51. Here, the numbers and the layout of the inverting devices 30 and 31, the thickness measuring device 40, the etching devices 50 and 51, and the wafer transfer device 60 are not limited to the shown example.

The inverting devices 30 and 31 are configured to invert the first surface Wa and the second surface Wb of the wafer W in the vertical direction. The configuration of the inverting devices 30 and 31 is not particularly limited.

The thickness measuring device 40 includes, as an example, a measurement device (not shown) and a calculation device (not shown). The measurement device is equipped with a sensor configured to measure the thickness of the wafer W after being etched at multiple points. The calculation device acquires a thickness distribution of the wafer W from the measurement result (thickness of the wafer W) by the measurement device. Further, the calculation device may also calculate flatness (TTV: Total Thickness Variation) of the wafer W. Here, the calculation of the thickness distribution and the flatness of the wafer W may be performed by a control device 150 to be described later, instead of the calculation device. In other words, the calculation device (not shown) may be provided in the control device 150 to be described later. Additionally, the configuration of the thickness measuring device 40 is not limited to this example, and may be modified in various ways.

The etching device 50 (51) is configured to etch silicon (Si) of the first surface Wa or the second surface Wb after being ground by a processing device 110 to be described later. Further, the etching device 50 (51) is also configured to clean the etched first surface Wa or second surface Wb to remove a metal adhering to the first surface Wa or the second surface Wb. A detailed configuration of the etching device 50 (51) will be described later.

The wafer transfer device 60 has, for example, two transfer arms 61 serving to hold and transfer the wafer W. Each transfer arm 61 is configured to be movable in a horizontal direction and a vertical direction and pivotable around a horizontal axis and a vertical axis. The wafer transfer device 60 is configured to transfer the wafer W to/from the cassette C of the cassette placing table 20, the inverting devices 30 and 31, the thickness measuring device 40, the etching devices 50 and 51, a buffer device 70 to be described later, a cleaning device 80 to be described later, and an inverting device 90 to be described later.

The second processing block G2 is equipped with the buffer device 70, the cleaning device 80, the inverting device 90, and the wafer transfer device 100. The buffer device 70, the cleaning device 80, and the inverting device 90 are stacked in this order from the bottom in the vertical direction, for example. The wafer transfer device 100 is disposed on the negative Y-axis side of the buffer device 70, the cleaning device 80, and the inverting device 90. Further, the numbers and the layout of the buffer device 70, the cleaning device 80, the inverting device 90, and the wafer transfer device 100 are not limited to the shown example.

The buffer device 70 is configured to temporarily hold the wafer W before being processed when it is transferred from the first processing block G1 to the second processing block G2. The configuration of the buffer device 70 is not particularly limited.

The cleaning device 80 is configured to clean the first surface Wa or the second surface Wb after being ground by the processing device 110 to be described later. For example, a brush may be brought into contact with the first surface Wa or the second surface Wb to scrub-clean the first surface Wa or the second surface Wb. Further, a pressurized cleaning liquid may be used to clean the first surface Wa or the second surface Wb. In addition, the cleaning device 80 may be configured to clean the first surface Wa and the second surface Wb at the same time when cleaning the wafer W.

Like the inverting devices 30 and 31, the inverting device 90 is configured to invert the first surface Wa and the second surface Wb of the wafer W in the vertical direction. The configuration of the inverting device 90 is not particularly limited.

The wafer transfer device 100 has, for example, two transfer arms 101 serving to hold and transfer the wafer W. Each transfer arm 101 is configured to be movable in the horizontal direction and the vertical direction and pivotable around a horizontal axis and a vertical axis. The wafer transfer device 100 is configured to transfer the wafer W to/from the etching devices 50 and 51, the buffer device 70, the cleaning device 80, the inverting device 90, and the processing device 110 to be described later.

The third processing block G3 is equipped with the processing device 110. Here, the number and the layout of the processing device 110 are not limited to the shown example.

The processing device 110 has a rotary table 111. The rotary table 111 is configured to be rotatable about a vertical rotation center line 112 by a rotating mechanism (not shown). On the rotary table 111, four chucks 113 are provided to attract and hold the wafer W. Among the four chucks 113, the two first chucks 113a are used to grind the first surface Wa, and are configured to attract and hold the second surface Wb. These two first chucks 113a are positioned point-symmetrically with the rotation center line 112 therebetween. The rest two second chucks 113b are used to grind the second surface Wb, and are configured to attract and hold the first surface Wa. These two second chucks 113b are positioned point-symmetrically with the rotation center line 112 therebetween. That is, the first chucks 113a and the second chucks 113b are alternately arranged in a circumferential direction. For example, a porous chuck is used as the chuck 113. Further, the porous chuck of the chuck 113 contains a metal such as alumina, for example.

The four chucks 113 can be moved to delivery positions A1 and A2 and the processing positions B1 and B2 as the rotary table 111 is rotated. Further, each of the four chucks 113 is configured to be rotatable around a vertical axis by a rotating mechanism (not shown).

The first delivery position A1 is a position on the negative X-axis and positive Y-axis side of the rotary table 111, where the wafer W is delivered onto the first chuck 113a when grinding the first surface Wa. The second delivery position A2 is a position on the negative X-axis and negative Y-axis side of the rotary table 111, where the wafer W is delivered onto the second chuck 113b when grinding the second surface Wb.

Disposed at the delivery positions A1 and A2 is a thickness measurer 120 which is configured to measure the thickness of the wafer W after being ground. As an example, the thickness measurer 120 includes a measurement device (not shown) and a calculation device (not shown). The measurement device is equipped with a non-contact type sensor that measures the thickness of the wafer W at multiple points. The calculation device 122 acquires a thickness distribution of the wafer W from the measurement result (thickness of the wafer W) obtained by the measurement device 121, and calculates flatness of the wafer W. In addition, the calculation of the thickness distribution and the flatness of the wafer W may be performed by the control device 150 to be described later, instead of calculation. In other words, a calculation device (not shown) may be provided in the control device 150 to be described later. Additionally, the thickness measurer 120 may be disposed at the processing positions B1 and B2.

The first processing position B1 is a position on the positive X-axis and negative Y-axis side of the rotary table 111, and a first grinding device 130 as a grinder is disposed thereat. The second processing position B2 is a position on the positive X-axis and positive Y-axis side of the rotary table 111, and a second grinding device 140 as the grinder is disposed thereat.

The first grinding device 130 is configured to grind the first surface Wa of the wafer W held by the first chuck 113a. The first grinding device 130 includes a first grinder 131 equipped with a grinding whetstone (not shown) configured to be rotatable in an annular shape. Further, the first grinder 131 is configured to be movable in a vertical direction along a support column 132.

The second grinding device 140 is configured to grind the second surface Wb of the wafer W held by the second chuck 113b. The second grinding device 140 has the same configuration as the first grinding device 130. That is, the second grinding device 140 has a second grinder 141 and a support column 142.

The above-described wafer processing system 1 is provided with the control device 150. The control device 150 is, by way of example, a computer equipped with a CPU, a memory, and the like, and has a program storage (not shown). The program storage stores therein a program for controlling a processing of the wafer W in the wafer processing system 1. Further, the program may have been recorded on a computer-readable recording medium H, and may be installed from the recording medium H into the control device 150. The recording medium H may be transitory or non-transitory.

Now, a detailed configuration of the aforementioned etching devices 50 and 51 will be explained. Although only the configuration of the etching device 50 will be described in the following, the etching device 51 has the same configuration.

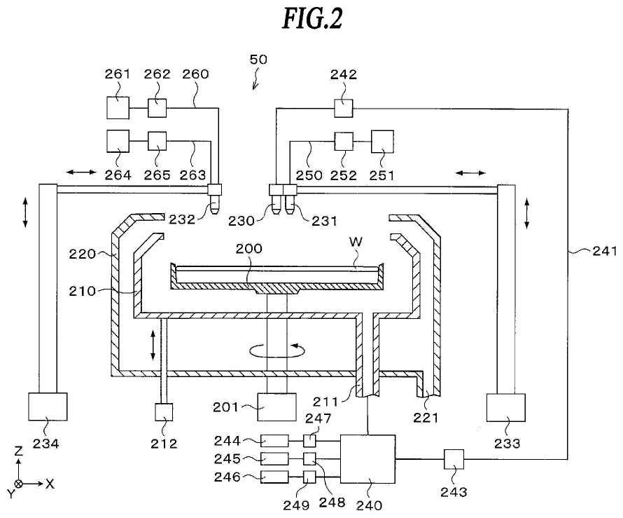

As depicted in FIG. 2, the etching device 50 has a wafer holder 200 serving as a substrate holder configured to hold the wafer W. The wafer holder 200 holds an edge of the wafer W at multiple points (three points in the present exemplary embodiment). The configuration of the wafer holder 200 is not limited to the shown example, and the wafer holder 200 may be equipped with a chuck (not shown) configured to attract and hold the wafer W from below, for example. The wafer holder 200 is configured to be rotatable around a vertical axis by a rotating mechanism 201 to thereby rotate the wafer W held on the wafer holder 200.

An inner cup 210 and an outer cup 220 are provided around the wafer holder 200. The inner cup 210 is configured to surround the wafer holder 200, and serves to collect the etching liquid as will be described later. A drain line 211 configured to drain the collected etching liquid is connected to the inner cup 210. Further, the inner cup 210 is configured to be movable up and down by an elevating mechanism 212.

The outer cup 220 is disposed outside the inner cup 210 to surround the wafer holder 200, and serves to collect a rinse liquid or a cleaning liquid as will be described later. A drain line 221 configured to drain the collected rinse liquid or cleaning liquid is connected to the outer cup 220. In the present exemplary embodiment, the outer cup 220 is not moved up and down, but it may be configured to be movable up and down by an elevating mechanism (not shown).

An etching liquid nozzle 230 as an etching liquid supply, a rinse liquid nozzle 231, and a cleaning liquid nozzle 232 as a cleaning liquid supply are provided above the wafer holder 200. The etching liquid nozzle 230 and the rinse liquid nozzle 231 are configured as one body, and are configured to be movable in a horizontal and a vertical direction by a moving mechanism 233. Further, the cleaning liquid nozzle 232 is configured to be movable in a horizontal direction and a vertical direction by a moving mechanism 234. Here, the number of the moving mechanisms configured to move these liquid nozzles is not limited to the shown example. For example, the etching liquid nozzle 230, the rinse liquid nozzle 231, and the cleaning liquid nozzle 232 may be provided as one body, and there may be provided only one moving mechanism. Alternatively, the etching liquid nozzle 230, the rinse liquid nozzle 231, and the cleaning liquid nozzle 232 may be provided separately, and there may be provided three moving mechanisms.

The etching liquid nozzle 230 supplies the etching liquid to the first surface Wa or the second surface Wb of the wafer W held by the wafer holder 200 to etch the first surface Wa or the second surface Wb. The etching liquid includes hydrofluoric acid (HF), nitric acid (HNO₃), and phosphoric acid (H₃PO₄). As an example, an etching liquid E is an aqueous solution containing hydrofluoric acid, nitric acid, phosphoric acid and water.

In the present exemplary embodiment, the etching liquid is reused to etch a plurality of wafers W. That is, the etching liquid used for one wafer W is collected and reused to etch the next wafer W. To this end, the etching device 50 is provided with an etching liquid recycling device 240.

The etching liquid recycling device 240 is connected with the drain line 211. Further, the etching liquid recycling device 240 is connected with a liquid feed line 241, and the liquid feed line 241 is connected to the etching liquid nozzle 230. The liquid feed line 241 is provided with a valve 242 configured to control a supply of the etching liquid. Further, the liquid feed line 241 is also provided with a concentration meter 243 configured to measure the concentration (mass percent concentration) of the etching liquid. The concentration meter 243 is capable of measuring the concentrations of respective components contained in the etching liquid, such as hydrofluoric acid, nitric acid, and phosphoric acid.

The etching liquid recycling device 240 has, for example, a tank configured to store the etching liquid therein. A hydrofluoric acid source 244, a nitric acid source 245, and a phosphoric acid source 246 are connected to the etching liquid recycling device 240. The hydrofluoric acid source 244, the nitric acid source 245, and the phosphoric acid source 246 store therein hydrofluoric acid, nitric acid, and phosphoric acid therein, respectively, and supply the hydrofluoric acid, the nitric acid, and the phosphoric acid to the etching liquid inside the etching liquid recycling device 240. A valve 247 configured to control the supply of the hydrofluoric acid is provided between the hydrofluoric acid source 244 and the etching liquid recycling device 240; a valve 248 configured to control the supply of the nitric acid, between the nitric acid source 245 and the etching liquid recycling device 240; and a valve 249 configured to control the supply of the phosphoric acid, between the phosphoric acid source 246 and the etching liquid recycling device 240.

In this case, the etching liquid collected into the inner cup 210 is drained into the etching liquid recycling device 240 through the drain line 211. In the etching liquid recycling device 240, the composition ratio of the etching liquid is adjusted by supplying one or more of the hydrofluoric acid, the nitric acid, and the phosphoric acid to the etching liquid from the hydrofluoric acid source 244, the nitric acid source 245, and the phosphoric acid source 246. Then, the etching liquid whose composition ratio has been adjusted is supplied to the etching liquid nozzle 230 through the liquid feed line 241. By reusing the etching liquid in this way, the amount of consumption of the etching liquid can be reduced, so that the cost can be reduced.

The rinse liquid nozzle 231 supplies the rinse liquid to the first surface Wa or the second surface Wb of the wafer W held by the wafer holder 200 to rinse the first surface Wa or the second surface Wb. The rinse liquid nozzle 231 is connected with a liquid feed line 250, and the liquid feed line 250 is connected to a rinse liquid source 251. The rinse liquid source 251 stores the rinse liquid therein. The liquid feed line 250 is provided with a valve 252 configured to control the supply of the rinse liquid. In addition, pure water is used as a rinse liquid, for example.

The cleaning liquid nozzle 232 supplies the cleaning liquid to the first surface Wa or the second surface Wb of the wafer W held by the wafer holder 200 to remove the metal adhering to the first surface Wa or the second surface Wb. A two-fluid nozzle is used as the cleaning liquid nozzle 232.

The cleaning liquid nozzle 232 is connected with a liquid feed line 260, and the liquid feed line 260 is connected to a cleaning liquid source 261. The cleaning liquid source 261 stores the cleaning liquid therein. The liquid feed line 260 is provided with a valve 262 configured to control the supply of the cleaning liquid. As the cleaning liquid, one capable of removing metal from the first surface Wa or the second surface Wb of the wafer W is used. For example, hydrofluoric acid, a mixture of hydrofluoric acid and hydrogen peroxide (FPM), or the like may be used.

Further, the cleaning liquid nozzle 232 is connected with a gas feed line 263, and the gas feed line 263 is connected to a gas source 264. The gas source 264 stores therein a gas such as a nitrogen gas, which is an inert gas. The gas feed line 263 is provided with a valve 265 configured to control the supply of the gas.

In the cleaning liquid nozzle 232, the cleaning liquid from the liquid feed line 260 and a gas from a gas feed line 263 are mixed, and this mixture is discharged to the first surface Wa or the second surface Wb of the wafer W. By discharging the cleaning liquid in this way, the metal is removed not only by the chemical action of the cleaning liquid but also by a physical impact force of the cleaning liquid.

Now, a wafer processing performed by using the wafer processing system 1 configured as described above will be explained. In the present exemplary embodiment, the wafer W, on which lapping is performed after being cut out from an ingot with a wire saw or the like, is subjected to a processing of improving in-surface uniformity of the thickness thereof.

First, the cassette C accommodating therein the plurality of wafers W is placed on the cassette placing table 20 of the carry-in/out station 10. In the cassette C, the wafer W is accommodated with the first surface Wa facing upwards and the second surface Wb facing downwards. Then, the wafer W in the cassette C is taken out by the wafer transfer device 60 and transferred to the buffer device 70.

Thereafter, the wafer W is transferred to the processing device 110 by the wafer transfer device 100, and delivered to the first chuck 113a at the first delivery position A1. Here, the second surface Wb of the wafer W is attracted to and held on the first chuck 113a.

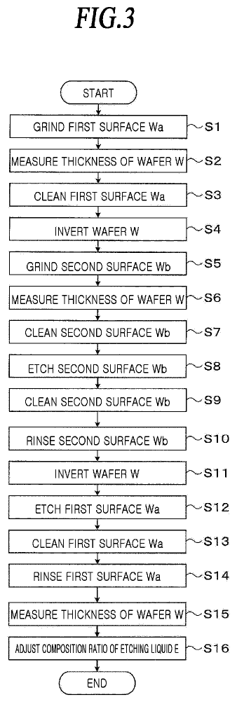

Next, the rotary table 111 is rotated to move the wafer W to the first processing position B1. Then, the first surface Wa of the wafer W is ground by the first grinding device 130 (process S1 in FIG. 3).

Subsequently, the rotary table 111 is rotated to move the wafer W to the first delivery position A1. At the first delivery position A1, the first surface Wa of the wafer W after being ground may be cleaned by a cleaning device (not shown).

Further, at the delivery position A1, the thickness of the wafer W after being ground by the first grinding device 130 is measured by the thickness measurer 120 (process S2 in FIG. 3).

Here, as described above, the thickness measurer 120 measures the thickness of the wafer W after being ground at multiple points to obtain the thickness distribution of the wafer W whose first surface Wa has been ground, and also calculates the flatness of the wafer W. The calculated thickness distribution and flatness of the wafer W may be outputted to, for example, the control device 150 to be used for the grinding of another wafer W to be held by the first chuck 113a (to be ground by the first grinding device 130) next. Specifically, based on the acquired thickness distribution and flatness of the wafer W, the relative inclination between the surface of the grinding whetstone and the surface of the first chuck 113a when grinding the next wafer W is adjusted to improve the thickness distribution and the flatness of the next wafer W after being ground by the first grinding device 130.

Next, the wafer W is transferred to the cleaning device 80 by the wafer transfer device 100. In the cleaning device 80, the first surface Wa of the wafer W is cleaned (process S3 in FIG. 3).

Then, the wafer W is transferred to the inverting device 90 by the wafer transfer device 100. In the inverting device 90, the first surface Wa and the second surface Wb of the wafer W are inverted in the vertical direction (process S4 in FIG. 3). That is, the wafer W is inverted with the first surface Wa facing downwards and the second surface Wb facing upwards.

Subsequently, the wafer W is transferred to the processing device 110 by the wafer transfer device 100, and delivered to the second chuck 113b at the second delivery position A2. Here, the first surface Wa of the wafer W is attracted to and held by the second chuck 113b.

Thereafter, the rotary table 111 is rotated to move the wafer W to the second processing position B2. Then, the second surface Wb of the wafer W is ground by the second grinding device 140 (process S5 in FIG. 3).

Next, the rotary table 111 is rotated to move the wafer W to the second delivery position A2. At the second delivery position A2, the second surface Wb of the wafer W after being ground may be cleaned by a cleaning device (not shown).

Further, at the delivery position A2, the thickness of the wafer W after being ground by the second grinding device 140 is measured by the thickness measurer 120 (process S6 in FIG. 3). In the process S6, the same processing as in the process S2 is performed. That is, the thickness measurer 120 acquires the thickness distribution of the wafer W after the grinding of the second surface Wb, and calculates the flatness of the wafer W. Then, based on the calculated thickness distribution and flatness of the wafer W, the relative inclination between the surface of the grinding whetstone of the second grinding device 140 and the surface of the second chuck 113b in the grinding of the next wafer W is adjusted.

Next, the wafer W is transferred to the cleaning device 80 by the wafer transfer device 100. In the cleaning device 80, the second surface Wb of the wafer W is cleaned (process S7 in FIG. 3).

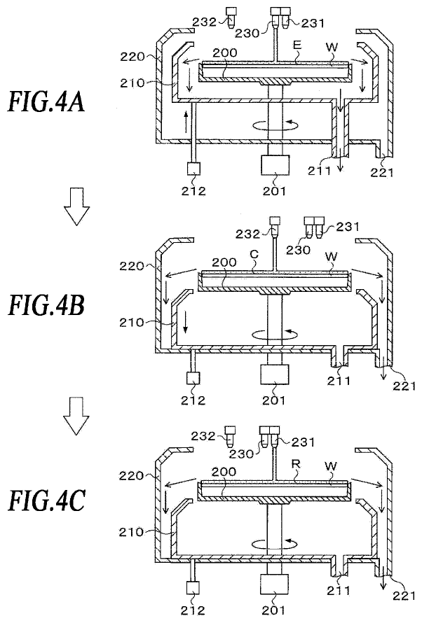

Then, the wafer W is transferred to the etching device 50 by the wafer transfer device 60. In the etching device 50, the first surface Wa of the wafer W is held by the wafer holder 200 with the second surface Wb facing upwards, as illustrated in FIG. 4A. At this time, the inner cup 210 is raised and positioned to surround the wafer holder 200. Subsequently, the etching liquid nozzle 230 is moved to above a central portion of the wafer W. Then, while rotating the wafer W, the etching liquid E is supplied from the etching liquid nozzle 230 to the second surface Wb while the etching liquid nozzle 230 is being moved between a position above the central portion of the wafer W and a position above an outer peripheral portion of the wafer W. As a result, the etching liquid E is supplied to the entire second surface Wb, so that the entire second surface Wb is etched (process S8 in FIG. 3).

The etching amount of the second surface Wb in the process S8 is, for example, 5 μm or less. When the etching amount is this small, the time required for the etching can be shortened, so that the throughput of the wafer processing can be improved. Further, the amount of the etching liquid used for etching can be reduced.

Also, the etching liquid E used in the process S8 is collected into the inner cup 210 and drained into the etching liquid recycling device 240 via the drain line 211. Then, the etching liquid E is supplied from the etching liquid recycling device 240 to the etching liquid nozzle 230 via the liquid feed line 241 to be reused to etch the next wafer W.

Subsequently, as illustrated in FIG. 4B, the cleaning liquid nozzle 232 is moved to above the central portion of the wafer W. Further, the inner cup 210 is lowered so that the outer cup 220 surrounds the wafer holder 200. Then, while rotating the wafer W, the cleaning liquid C is supplied from the cleaning liquid nozzle 232 to the second surface Wb while the cleaning liquid nozzle 232 is being moved between the position above the central portion and the outer peripheral portion of the wafer W. As a result, the cleaning liquid C is supplied to the entire second surface Wb, so that the entire second surface Wb is cleaned (process S9 in FIG. 3). The cleaning liquid C used in the process S9 is collected into the outer cup 220 and drained from the drain line 221.

Here, when grinding the first surface Wa of the wafer W in the process S1, the second surface Wb is attracted to and held by the first chuck 113a. At this time, since the first chuck 113a, which is a porous chuck, contains a metal, the metal may adhere to the second surface Wb. In addition, when etching the second surface Wb with the etching liquid E in the process S8, the etching amount is small (5 μm or less), so the metal attached to the second surface Wb may not be completely removed in this etching.

As a resolution, in the process S9, the cleaning liquid C is supplied to the second surface Wb to remove the metal adhering to the second surface Wb. Specifically, the metal is lifted off and removed from the second surface Wb by the cleaning liquid C. Further, since the cleaning liquid nozzle 232 as the two-fluid nozzle discharges the cleaning liquid C to the second surface Wb, the metal is removed even by the physical impact force of the cleaning liquid C.

Additionally, in the process S9, since the cleaning liquid C is supplied to the second surface Wb from the cleaning liquid nozzle 232 while moving the cleaning liquid nozzle 232 between the position above the central portion and the outer peripheral portion of the wafer W, the cleaning liquid C is supplied to the entire second surface Wb. Furthermore, the physical impact force of the cleaning liquid C mentioned above is also applied to the entire second surface Wb. Therefore, the metal can be removed from the second surface Wb.

Next, as shown in FIG. 4C, the rinse liquid nozzle 231 is moved to above the central portion of the wafer W. At this time, the inner cup 210 is lowered, and the outer cup 220 is positioned to surround the wafer holder 200. Then, while rotating the wafer W, the rinse liquid R is supplied from the rinse liquid nozzle 231 to the central portion of the second surface Wb. As a result, the rinse liquid R is diffused to the outer peripheral portion due to a centrifugal force, so that the entire second surface Wb is rinsed (process S10 in FIG. 3). Further, the rinse liquid R used in the process S10 is collected into the outer cup 220 and drained from the drain line 221. Additionally, it is desirable that the supply of the rinse liquid R is also performed between the processes S8 and S9.

Next, in the state that the supply of rinse liquid R from the rinse liquid nozzle 231 is stopped, the rotation of the wafer W is carried on. As a consequence, the second surface Wb is dried.

Next, the wafer W is transferred to the inverting device 31 by the wafer transfer device 60. In the inverting device 31, the first surface Wa and the second surface Wb of the wafer W are inverted in the vertical direction (process S11 in FIG. 3). That is, the wafer W is inverted with the first surface Wa facing upwards and the second surface Wb facing downwards.

Thereafter, the wafer W is transferred to the etching device 51 by the wafer transfer device 60. In the etching device 51, the second surface Wb of the wafer W is held by the wafer holder 200 with the first surface Wa facing upwards. Then, while rotating the wafer W, the etching liquid E is supplied from the etching liquid nozzle 230 to the first surface Wa while the etching liquid nozzle 230 is being moved between the position above the central portion and the outer peripheral portion of the wafer W. As a result, the etching liquid E is supplied to the entire first surface Wa, so that the entire first surface Wa is etched (process S12 in FIG. 3). This etching of the first surface Wa is the same as the etching of the second surface Wb in the process S8, and its etching amount is also, for example, 5 um or less.

Next, in the etching device 51, while rotating the wafer W, the cleaning liquid C is supplied from the cleaning liquid nozzle 232 to the first surface Wa while the cleaning liquid nozzle 232 is being moved between the position above the central portion and the position above the outer peripheral portion of the wafer W. As a result, the first surface Wa is cleaned, and the metal adhering to the first surface Wa is removed (process S13 in FIG. 3). This cleaning of the first surface Wa is the same as the cleaning of the second surface Wb in the process S9.

Subsequently, in the etching device 51, while rotating the wafer W, the rinse liquid R is supplied from the rinse liquid nozzle 231 to the central portion of the first surface Wa, so that the first surface Wa is rinsed (process S14 in FIG. 3). This rinsing of the first surface Wa is the same as the rinsing of the second surface Wb in the process S10. In addition, it is desirable that the supply of the rinse liquid R is also performed between the processes S12 and S13.

Thereafter, the wafer W is transferred to the thickness measuring device 40 by the wafer transfer device 60. The thickness measuring device 40 measures the thickness distribution of the wafer W after being etched by the etching device 51 (process S15 in FIG. 3).

In the process S15, the thickness distribution of the wafer W after being etched is obtained by measuring the thickness of the wafer W at multiple points as described above. The acquired thickness distribution of the wafer W is outputted to the control device 150, for example. Based on the thickness distribution of the wafer W, the control device 150 adjusts the composition ratio of the etching liquid E to be used for the next wafer W to be etched (process S16 in FIG. 3). The way to adjust the composition ratio of this etching liquid E will be described later.

Meanwhile, the wafer W whose thickness distribution has been measured by the thickness measuring device 40 is then transferred to the cassette C of the cassette placing table 20 by the wafer transfer device 60. In this way, the series of processes of the wafer processing in the wafer processing system 1 is ended. Additionally, the wafer W after being subjected to the required processing in the wafer processing system 1 may be polished outside the wafer processing system 1.

According to the above-described exemplary embodiment, in the processes S9 and S13, the surface of the wafer W is cleaned by using the cleaning liquid C, so that the metal adhering to the surface of the wafer W can be removed. Besides, since the cleaning liquid C is discharged to the surface of the wafer W from the cleaning liquid nozzle 232, which is a two-fluid nozzle, physical metal removing ability of the cleaning liquid C due to its impact force is demonstrated in addition to the chemical metal removing ability of the cleaning liquid C, allowing the metal to be removed efficiently. As a result, it becomes possible to maintain product performance of the wafer W.

Further, when the chemical metal removing ability of the cleaning liquid C is sufficient, a normal nozzle, rather than the two-fluid nozzle, may be used as the cleaning liquid nozzle 232. In this case, the cleaning liquid C may be supplied from the cleaning liquid nozzle 232 to the central portion of the wafer W, and the cleaning liquid C may be diffused to the outer peripheral portion by a centrifugal force. In this modification example, although the metal removing ability is inferior to that of the above-described exemplary embodiment, the cleaning liquid nozzle 232 is of a low price, so that the cost can be reduced.

Furthermore, when the physical metal removing ability of the cleaning liquid C is sufficient, pure water, rather than hydrofluoric acid or FPM, may be used as the cleaning liquid C, for example. In this modification example as well, although the metal removing ability is inferior to that of the above-described exemplary embodiment, the cleaning liquid C is of a low price, so that the cost can be reduced.

Now, a method of adjusting the composition ratio of the etching liquid E in the process S16 will be described.

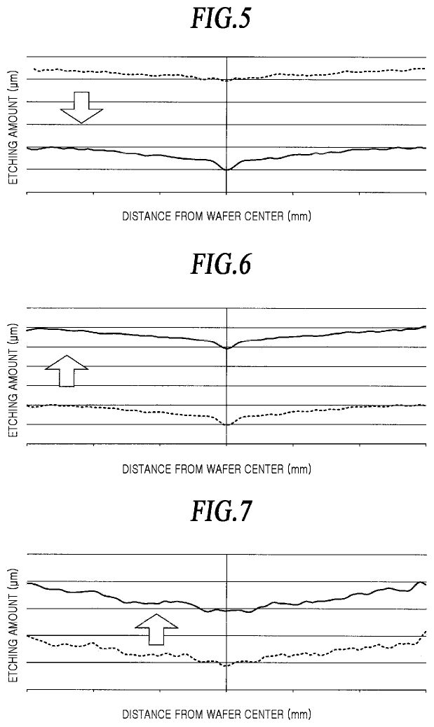

In the present exemplary embodiment, when etching the wafer W in the processes S8 and S12, the etching liquid E is reused for a plurality of wafers W. In this case, according to the research of the present inventors, it is found out that the composition ratio of the etching liquid E is changed due to the reaction between the wafer W (silicon) and the etching liquid E (mixed acid) in the etching. The present inventors have investigated a change in the etching liquid E over time and obtained a result shown in FIG. 5. In FIG. 5, a dotted line represents a distribution of the etching amount of the wafer W in a radial direction when the etching liquid E in an initial state is used. A solid line represents a distribution of the etching amount of the wafer W in the radial direction when the etching liquid E after being used to etch a predetermined number of wafers W is used. As shown in FIG. 5, when the etching liquid E is repeatedly reused, the etching amount decreases in overall. Further, the etching amount of the central portion of the wafer W becomes less than that of the outer peripheral portion thereof, which results in a change in an etching profile in the radial direction of the wafer W. As a result, process performance of the etching becomes unstable.

If the etching liquid E is repeatedly reused, the hydrofluoric acid in the etching liquid E is consumed. Due to such a decrease of the concentration of the hydrofluoric acid, the etching amount decreases as the etching liquid E is reused. In view of this, the present inventors have attempted to add hydrofluoric acid to the etching liquid E and obtained a result shown in FIG. 6. In FIG. 6, a dotted line represents a distribution of the etching amount of the wafer W in the radial direction when the wafer W is etched by reusing the etching liquid E without adding hydrofluoric acid to the reused etching liquid E. A solid line indicates a distribution of the etching amount of the wafer W in the radial direction when the wafer W is etched by reusing the etching liquid E after adding hydrofluoric acid to the reused etching liquid E. As depicted in FIG. 6, when the hydrofluoric acid is added to the etching liquid E, the overall etching amount of the wafer W increases. However, the etching profile is not improved, so that the etching amount of the central portion of the wafer W remains less than that of the outer peripheral portion thereof.

In addition, the present inventors have attempted to add hydrofluoric acid and nitric acid to the etching liquid E, and have obtained a result shown in FIG. 7. In FIG. 7, a dotted line represents a distribution of the etching amount of the wafer W in the radial direction when the wafer W is etched by reusing the etching liquid E without adding either hydrofluoric acid or nitric acid to the etching liquid E to be reused. A solid line shows a distribution of the etching amount of the wafer W in the radial direction when the wafer W is etched by reusing the etching liquid E after adding hydrofluoric acid and nitric acid to the etching liquid E to be reused. As depicted in FIG. 7, when the hydrofluoric acid and the nitric acid are added to the etching liquid E, the overall etching amount of the wafer W increases. However, the etching profile is still not improved, so that the etching amount of the central portion of the wafer W remains less than that of the outer peripheral portion thereof.

Additionally, in order to increase the overall etching amount, it is desirable to add nitric acid in addition to hydrofluoric acid. The hydrofluoric acid and the nitric acid chemically contribute to the etching of the wafer W, and a process in which the wafer W is etched by the hydrofluoric acid and oxidized by the nitric acid is repeated. For this reason, if the etching liquid E is repeatedly reused, the hydrofluoric acid and the nitric acid in the etching liquid E are consumed together. Since, however, the concentration of the nitric acid is larger than the concentration of the hydrofluoric acid, the decrease in the concentration of hydrofluoric acid has a larger effect on the etching even if the concentration of the nitric acid is reduced. For this reason, adding the hydrofluoric acid to the etching liquid E directly contributes to the increase of the etching amount. From a long-term perspective, however, it is desirable to add the nitric acid in addition to the hydrofluoric acid in order to maintain a concentration balance between the hydrofluoric acid and the nitric acid in the etching liquid E.

Here, the phosphoric acid in the etching liquid E does not chemically contribute to the etching of the wafer W, and is not consumed by the etching. However, when the wafer W is etched, water is generated as a by-product. For this reason, the concentration of the phosphoric acid becomes relatively low. Further, since the viscosity of the etching liquid E decreases with the decrease of the concentration of the phosphoric acid, the etching liquid E at the central portion of the wafer W being rotated during the etching may be easily diffused to the outer peripheral portion thereof. More specifically, when the viscosity of the etching liquid E is larger than the centrifugal force caused by the rotation of the wafer W, the etching liquid E tends to be easily diffused to the outer peripheral portion of the wafer W. For this reason, the etching amount of the central portion of the wafer W becomes less than that of the outer peripheral portion thereof.

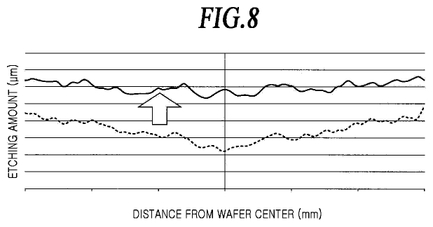

In view of the foregoing, the present inventors have attempted to add hydrofluoric acid, nitric acid, and phosphoric acid to the etching liquid E, and have obtained a result shown in FIG. 8. In FIG. 8, a dotted line represents a distribution of the etching amount of the wafer W in the radial direction when the wafer W is etched by reusing the etching liquid E without adding any of hydrofluoric acid, nitric acid, or phosphoric acid to the etching liquid E to be reused. A solid line indicates a distribution of the etching amount of the wafer W in the radial direction when the wafer W is etched by reusing the etching amount E after adding hydrofluoric acid, nitric acid, and phosphoric acid to the etching liquid E to be reused. As shown in FIG. 8, when the hydrofluoric acid, the nitric acid, and the phosphoric acid are added to the etching liquid E, the overall etching amount of the wafer W increases. Further, the etching amount of the central portion of the wafer W also increases, so that the etching profile is also improved.

Moreover, when only the phosphoric acid is added to the etching liquid E, the concentration of the hydrofluoric acid becomes relatively low, so the overall etching amount is reduced. For this reason, it is desirable to add the hydrofluoric acid as well when adding the phosphoric acid for the purpose of improving the etching profile.

In addition, the component added to the etching liquid E to improve the etching profile is not limited to the phosphoric acid. Any component can be added to the etching liquid E as long as it improves the viscosity of the etching liquid E without contributing to the etching of the wafer W.

Through intensive research as described above, the present inventors have reached the following findings.
When increasing the overall etching amount, hydrofluoric acid is added to the etching liquid.
When increasing the overall etching amount, it is desirable to further add nitric acid.
To improve the etching profile, phosphoric acid is added to the etching liquid.
To improve the etching profile, it is desirable to further add hydrofluoric acid.

Based on the above-described findings, the following controls (1) to (3) are performed when adjusting the composition ratio of the etching liquid E in the process S16.
(1) In the thickness distribution of the wafer W measured in the process S15, when the thickness of the wafer W is large in overall (when the etching amount is small), hydrofluoric acid is added to the etching liquid E. At this time, it is desirable to further add nitric acid. Here, the case where the thickness of the wafer W is large in overall indicates, for example, a case where the thickness of the wafer W measured in the process S15 is large in overall as compared to a target thickness of the wafer W after being etched.
(2) In the thickness distribution of the wafer W measured in the process S15, when the thickness of the central portion of the wafer W is larger than the thickness of the outer peripheral portion thereof (the etching amount of the central portion of the wafer W is smaller than the etching amount of the outer peripheral portion thereof), phosphoric acid is further added to the etching liquid E. At this time, it is desirable to add hydrofluoric acid as well.
(3) In the thickness distribution of the wafer W measured in the process S15, when the thickness of the wafer W is large in overall and the thickness of the central portion of the wafer W is larger than the thickness of the outer peripheral portion thereof, hydrofluoric acid and phosphoric acid are added to the etching liquid E. At this time, it is desirable to further add nitric acid.

In the above-described controls (1) to (3), the way to determine the amounts of the hydrofluoric acid, the nitric acid, and the phosphoric acid to be added to the etching liquid E is arbitrary. For example, the hydrofluoric acid, the nitric acid, and the phosphoric acid may be added in predetermined amounts, and the thickness distribution of the wafer W may be measured after the etching liquid E is used, to determine the amounts of the hydrofluoric acid, the nitric acid, and the phosphoric acid to be added. Alternatively, the amounts of the hydrofluoric acid, the nitric acid, and the phosphoric acid may be determined based on, for example, measurement results obtained by the concentration meter 243.

Then, the etching liquid E whose composition ratio has been adjusted by performing the above-described controls (1) to (3) is supplied from the etching liquid recycling device 240 to the etching liquid nozzle 230 through the liquid feed line 241 to be reused in the next etching.

Further, the adjustment of the composition ratio of the etching liquid E through the above-described controls (1) to (3) may be performed for each wafer W, or may be performed for a plurality of wafers W (for example, every single lot of 25 sheets of wafers W).

According to the above-described exemplary embodiment, based on the thickness distribution of the wafer W after being etched, which is measured in the process S15, one or more of hydrofluoric acid, nitric acid, and phosphoric acid may be added to the etching liquid E in the process S16 to adjust the composition ratio of the etching liquid E appropriately. Therefore, even if the etching liquid E is reused when etching a plurality of wafers W, the wafers W can be uniformly etched within their surfaces by using the etching liquid E whose composition ratio has been adjusted. Therefore, the surface shapes of the wafers W after being etched can be appropriately controlled.

Now, a method of adjusting the composition ratio of the etching liquid E in the process S16 according to another exemplary embodiment will be described. In the present exemplary embodiment, an etching amount is calculated from the thickness distribution of the wafer W after being etched, which is measured in the process S15, and an etching amount average and an etching amount range are also calculated. The etching amount average is an average value of the etching amounts within the surface of the wafer W. The etching amount range is a difference between a maximum value and a minimum value of the etching amount within the surface of the wafer W. The composition ratio of the etching liquid E is adjusted based on the calculated etching amount average and etching amount range.

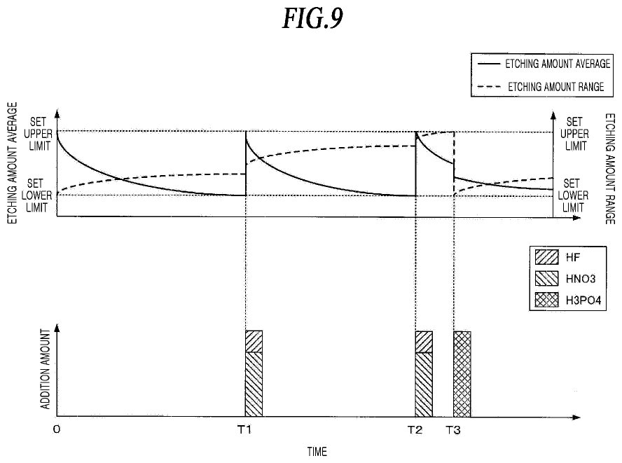

As shown in FIG. 9, when the etching liquid E is repeatedly reused, hydrofluoric acid and nitric acid in the etching liquid E are consumed, so that the overall etching amount of the wafer W decreases, and the etching amount average decreases. Then, if the etching amount average reaches a set lower limit (time T1 in FIG. 9), hydrofluoric acid and nitric acid are added (replenished) to the etching liquid E. The addition amounts of the hydrofluoric acid and the addition amount of the nitric acid at time T1 are set to preset values so that the etching amount average by the etching liquid E after being replenished with the hydrofluoric acid and the nitric acid becomes a set upper limit. As an example, by setting a target etching amount average and determining allowable lower and upper values from the target etching amount average, the set lower limit and the set upper limit of the etching amount average are set arbitrarily.

When the hydrofluoric acid and the nitric acid are added at time T1, the concentration of the hydrofluoric acid and the concentration of the nitric acid in the etching liquid E increases, so that the etching amount average by the etching liquid E increases up to the set upper limit. Here, the increase of the etching amount as a result of adding the hydrofluoric acid and the nitric acid is the same as stated above.

If the etching liquid E is then repeatedly reused, the etching amount average decreases again. Then, if the etching amount average reaches the set lower limit (time T2 in FIG. 9), hydrofluoric acid and nitric acid are added to the etching liquid E.

The addition amount of the hydrofluoric acid in time T2 is calculated using the following expressions (1) and (2). That is, by using the expression (1), an inclination a of the increment of the etching amount average with respect to the addition amount of the hydrofluoric acid at time T1 is first calculated. Next, by using the expression (2), the addition amount of the hydrofluoric acid at time T2 is calculated so that the etching amount average by the etching liquid E after being replenished with the hydrofluoric acid becomes the set upper limit.

$$a = \{ ( Etching amount average after addition ) - ( Etching amount average before addition ) \} / ( Addition amount of hydrofluoric acid at time T 1 ) \qquad ( 1 )$$

$$( Addition amount of hydrofluoric acid at time T 2 ) = \{ ( Set upper limit of etching amount average ) - ( Etching amount average after addition ) \} / a \qquad ( 2 )$$

The addition amount of the nitric acid at time T2 is also calculated by using the same calculation formulae as the expressions (1) and (2).

When the hydrofluoric acid and the nitric acid are added at time T2, the concentration of the hydrofluoric acid and the concentration of the nitric acid in the etching liquid E increases, so that the etching amount average by the etching liquid E increases up to the set upper limit.

If the etching liquid E is then repeatedly reused, the etching profile changes and the etching amount range increases. Then, when the etching amount range reaches a set upper limit (time T3 in FIG. 9), phosphoric acid is added to the etching liquid E. The addition amount of phosphoric acid at time T3 is set to a predetermined value so that the etching amount range by the etching liquid E after the addition becomes a set lower limit. As an example, by setting a target etching amount range and determining allowable upper and lower values from the target etching amount range, the set upper limit and the set lower limit of the etching amount range are arbitrarily set.

When the phosphoric acid is added at time T3, the etching amount range by the etching liquid E is reduced to the set lower limit, so that the etching profile is improved. Here, the addition of the phosphoric acid improves the etching profile as described above.

Additionally, the addition amount of the phosphoric acid from the second time may be calculated by using the same calculation formulae as the expressions (1) and (2).

As described above, in the present exemplary embodiment, an on/off control of adding one or more of hydrofluoric acid, nitric acid, and phosphoric acid is performed, as stated below.
When the etching amount average reaches the set lower limit, hydrofluoric acid and nitric acid are added to the etching liquid E.
When the etching amount range reaches the set upper limit, phosphoric acid is added to the etching liquid E.

By repeating these controls, the composition ratio of the etching liquid E can be adjusted appropriately. Moreover, since the addition amounts of the hydrofluoric acid, the nitric acid, and the phosphoric acid from the second time are calculated through the above-specified expressions (1) and (2) based on the etching amount, the hydrofluoric acid, the nitric acid, and the phosphoric acid can be added accurately. As a result, even when the etching liquid E is reused when etching a plurality of wafers W, the wafers W can be etched uniformly within their surfaces by using the etching liquid E whose composition ratio has been adjusted. Thus, the surface shapes of the wafers W after being etched can be appropriately controlled.

It should be noted that the above-described exemplary embodiment is illustrative in all aspects and is not anyway limiting. The above-described exemplary embodiment may be omitted, replaced and modified in various ways without departing from the scope and the spirit of claims.

### EXPLANATION OF CODES

1: Wafer processing system
40: Thickness measuring device
50: Etching device
51: Etching device
150: Control device
230: Etching liquid nozzle
240: Etching liquid recycling device

W: Wafer

1. A substrate processing method of processing a substrate, comprising:
etching a surface of the substrate by supplying an etching liquid containing hydrofluoric acid and phosphoric acid to the surface of the substrate;
collecting the etching liquid after being used in the etching;
measuring a thickness distribution of the substrate after being etched; and
adjusting a composition ratio of the etching liquid by adding, based on the measured thickness distribution, at least hydrofluoric acid or phosphoric acid to the etching liquid collected after being used in the etching.

2. The substrate processing method of claim 1,
wherein when a thickness of the substrate is large in overall in the thickness distribution, hydrofluoric acid is added to the etching liquid.

3. The substrate processing method of claim 2,
wherein when the thickness of the substrate is large in overall in the thickness distribution, nitric acid is further added to the etching liquid.

4. The substrate processing method of claim 1,
wherein when a thickness of a central portion of the substrate is larger than a thickness of an outer peripheral portion thereof in the thickness distribution, phosphoric acid is added to the etching liquid.

5. The substrate processing method of claim 1,
wherein the surface of the substrate is ground before being etched.

6. The substrate processing method of claim 1,
wherein an average value of an etching amount within the surface of the substrate is calculated from the thickness distribution, and hydrofluoric acid and nitric acid are added to the etching liquid when the calculated average value reaches a set lower limit.

7. The substrate processing method of claim 1,
wherein a difference between a maximum value and a minimum value of an etching amount within the surface of the substrate is calculated from the thickness distribution, and
phosphoric acid is added to the etching liquid when the calculated difference reaches a set upper limit.

8. A substrate processing system of processing a substrate, comprising:
an etching device configured to etch a surface of the substrate;
a thickness measuring device configured to measure a thickness distribution of the substrate; and
a control device and a program storage including a program,
wherein the etching device comprises:
an etching liquid supply configured to supply an etching liquid to the surface of the substrate; and
an etching liquid recycling device configured to collect the etching liquid and adjust a composition ratio of the etching liquid,
wherein the etching liquid contains hydrofluoric acid and phosphoric acid, and
wherein the program storage and the program are configured, with the control device, to perform:
etching the surface of the substrate by supplying the etching liquid to the surface of the substrate;
collecting the etching liquid after being used in the etching;
measuring the thickness distribution of the substrate after being etched; and
adjusting the composition ratio of the etching liquid by adding, based on the measured thickness distribution, at least hydrofluoric acid or phosphoric acid to the etching liquid collected after being used in the etching.

9. The substrate processing system of claim 8,
wherein the control device performs adding hydrofluoric acid to the etching liquid when a thickness of the substrate is large in overall in the thickness distribution.

10. The substrate processing system of claim 9,
wherein the control device performs further adding nitric acid to the etching liquid when the thickness of the substrate is large in overall in the thickness distribution.

11. The substrate processing system of claim 8,
wherein the control device performs adding phosphoric acid to the etching liquid when a thickness of a central portion of the substrate is larger than a thickness of an outer peripheral portion thereof in the thickness distribution.

12. The substrate processing system of claim 8, , further comprising:
a processing device configured to grind the surface of the substrate,
wherein the control device performs grinding the surface before the surface of the substrate is etched.

13. 3The substrate processing system of claim 8,
wherein the control device calculates an average value of an etching amount within the surface of the substrate from the thickness distribution, and adds hydrofluoric acid and nitric acid to the etching liquid when the calculated average value reaches a set lower limit.

14. The substrate processing system of claim 8,
wherein the control device calculates a difference between a maximum value and a minimum value of an etching amount within the surface of the substrate from the thickness distribution, and adds phosphoric acid to the etching liquid when the calculated difference reaches a set upper limit.
